(19) United States
(12) Patent Application Publication
(10) Pub. No.: US 2021/0193819 A1
(43) Pub. Date: Jun. 24, 2021

(54) THIN FILM TRANSISTOR ARRAY SUBSTRATE AND ITS MANUFACTURING METHOD AND OLED TOUCH DISPLAY DEVICE

(71) Applicant: WUHAN CHINA STAR OPTOELECTRONICS SEMICONDUCTOR DISPLAY TECHNOLOGY CO., LTD, Wuhan (CN)

(72) Inventors: Qi OUYANG, Wuhan (CN); Mugyeom KIM, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/822,035

(22) Filed: Mar. 18, 2020

(30) Foreign Application Priority Data
Dec. 18, 2019 (CN) 201911308475.6

(51) Int. Cl. H01L 29/66; H01L 51/56; H01L 27/32; H01L 51/52

(52) U.S. Cl. CPC H01L 29/6675; H01L 51/56; H01L 51/5293; H01L 27/3276; H01L 27/323; H01L 27/3246

(57) ABSTRACT

The present disclosure implements the LTPO and FOD techniques in a single process step and thus save processing time and reduce the cost. The LTPO, having lower power consumption, is utilized to drive OLEDs to generate light and the thin film optical fingerprint sensor is formed on the LTPO substrate to realize the under screen fingerprint identification. The gate of the oxide TFT and the gate or source/drain of the LTPS TFT are formed at the same time to save the cost of the mask. Accordingly, the display could reduce power consumption and have higher screen ratio and under screen fingerprint function.

### FIELD OF THE INVENTION

The present invention relates to a display technique, and more particularly, to a thin film transistor array substrate and its manufacturing method and an OLED touch display device.

### BACKGROUND OF THE INVENTION

OLED displays are different from the LCD displays. OLED displays adopt organic light emitting materials and thus do not need the backlight lamps. When currents flow through the organic light emitting materials, the organic light emitting materials generate light. Through spreading very thin organic light emitting material coating layer, the OLED display panel could be very thin. Furthermore, the OLED display panel could have a larger view angle and could reduce significant power consumption.

Low temperature poly-oxide (LTPO) thin film transistor (TFT) technique is a new TFT technique. Theoretically, LTPO TFT could save 5-15% power consumption in contrast to the traditional low temperature poly-silicon (LTPS) TFT technique. Therefore, the LTPO TFT could allow the display panel to have lower power consumption. However, the LTPO technique requires more patterning processes and thus cost more.

Following the development of full screen, the fingerprint sensor on display (FOD) is successful. FOD could be implemented by optical under screen fingerprint technique, supersonic under screen fingerprint technique, and thin film optical fingerprint sensor technique (TFT adoption scheme). The theory of the TFT adoption scheme is: utilizing a light sensing device of pixels to obtain fingerprint information from the light reflected from the cover plate (window) glass; converting the light signals to a 16-digit digital signal by an analog/digital converter for data analysis; and output a complete and clear fingerprint image after image processing technique.

As the higher demands of the display device, the display device is required to have lower power consumption, the under screen fingerprint technology and high screen ratio. How to achieve these goals becomes the technical challenge.

### SUMMARY OF THE INVENTION

One objective of an embodiment of the present invention is to provide a thin film transistor array substrate and its manufacturing method and an OLED touch display device to make it possible to have a display device having a lower power consumption, the under screen fingerprint technology and high screen ratio.

According to an embodiment of the present invention, a manufacturing method for manufacturing a thin film transistor (TFT) array substrate is disclosed. The manufacturing method comprises: providing a substrate comprising a plurality of pixel driving areas and at least one under screen fingerprint area; forming a first low temperature poly-silicon (LTPS) TFT and a first oxide TFT on the pixel driving areas wherein a gate of the first oxide TFT and a source/drain or a gate of the first LTPS TFT are formed through one patterning process; and forming a third TFT on the under screen fingerprint area; wherein the first LTPS TFT is configured to drive a pixel to generate light, the first oxide TFT is configured to perform a switch control, and the third TFT is configured to perform a fingerprint identification.

According to an embodiment of the present invention, a TFT array substrate is disclosed. The TFT array substrate comprises: a substrate, comprising a plurality of pixel driving areas and at least one under screen fingerprint area; a first LTPS TFT, positioned on the pixel driving area, configured to drive a pixel to generate light; a first oxide TFT, positioned on the pixel driving area, configured to perform a switch control, wherein a gate of the first oxide TFT and a source/drain or a gate of the first LTPS TFT are in a same layer; and a third TFT, positioned on the under screen fingerprint area, configured to perform a fingerprint identification.

According to an embodiment of the present invention, an organic light emitting diode (OLED) display is disclosed. The OLED display comprises: the above-mentioned TFT array substrate; an organic light emitting layer, positioned on the TFT array substrate; a cathode layer, positioned on the organic light emitting layer; a thin film packaging layer, positioned on the cathode layer; a touch control layer, positioned on the thin film packaging layer; a polarizer, positioned on the touch control layer; and a cover plate (window), positioned on the polarizer.

In contrast to the conventional art, an embodiment of the present invention could implement the LTPO and FOD techniques in a single process step and thus save processing time and reduce the cost. Furthermore, in an embodiment, LTPO, having lower power consumption, is utilized to drive OLEDs to generate light and the thin film optical fingerprint sensor is formed on the LTPO substrate to realize the under screen fingerprint identification. In particular, the gate of the oxide TFT and the gate or source/drain of the LTPS TFT are formed at the same time to save the cost of the mask. In addition, the oxide TFT or the LTPS TFT is adopted as the under screen fingerprint sensor to realize the light sensing function. That is, the light generated by the organic light emitting layer is reflected by the cover plate (window) of the display and then enters the sensor. The sensor senses the luminance change to generate a variance of a light current and thus realizes the fingerprint identification. In this way, the display could reduce power consumption and have higher screen ratio and under screen fingerprint function.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a flow chart of a manufacturing method of a TFT array substrate according to an embodiment of the present invention.

FIG. 2A-FIG. 2C depict structures at steps of a manufacturing method of a TFT array substrate according to an embodiment of the present invention.

FIG. 3 is a diagram of a film layer structure of an OLED touch display device according to a first embodiment of the present invention.

FIG. 4 is a diagram of a distribution of the fingerprint sensor according to an embodiment of the present invention.

FIG. 5 is a diagram of a film layer structure of an OLED touch display device according to a second embodiment of the present invention.

FIG. 6 is a diagram of a film layer structure of an OLED touch display device according to a third embodiment of the present invention.

FIG. 7 is a diagram of a film layer structure of an OLED touch display device according to a fourth embodiment of the present invention.

### DETAILED DESCRIPTION OF PREFERRED EMBODIMENTS

Specifically, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined. In addition, to simplify the method, only specific components and devices are elaborated by the present disclosure. These embodiments are truly exemplary instead of limiting the present disclosure. Identical numbers and/or letters for reference are used repeatedly in different examples for simplification and clearance. It does not imply that the relations between the methods and/or arrangement. The methods proposed by the present disclosure provide a variety of examples with a variety of processes and materials. However, persons skilled in the art understand ordinarily that the application of other processes and/or the use of other kinds of materials are possible.

An embodiment of the present invention provides a design of a TFT array substrate, which could manufacture the LTPO and FOD techniques in a single process step. This saves the manufacturing time and reduces the cost. The substrate integrates the LTPO and FOD techniques and utilizes the LTPO, having higher response speed and lower power consumption, to generate light. Further, the thin film optical fingerprint sensor is simultaneously manufactured on the LTPO substrate to realize under screen fingerprint identification. The LTPS TFT is used to drive TFTs and the oxide TFTs are used as switch TFTs. Because the LTPS TFT has a higher mobility and a smaller size, the side frame size is effectively reduced. Furthermore, the oxide TFT can be driven at a low frequency, the power consumption could be effectively reduced. In addition, the gate of the oxide TFT and the gate or source/drain of the LTPS TFT are manufactured at the same time. This could reduce the cost of masks. The oxide TFT (or the LTPS TFT) is used as the under screen fingerprint sensor to realize the light sensing function. The light generated by the organic light emitting layer is reflected by the cover plate (window) of the display and enters the oxide TFT. The oxide TFT senses the luminance change to generate a variance of a light current and thus realizes the fingerprint identification. In this way, the display could reduce power consumption and have higher screen ratio and under screen fingerprint function.

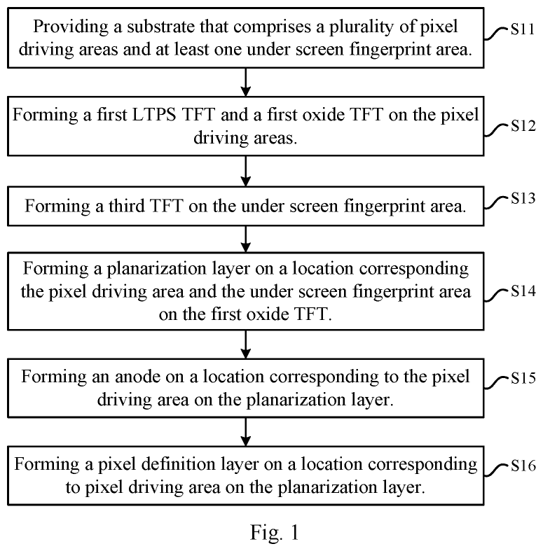

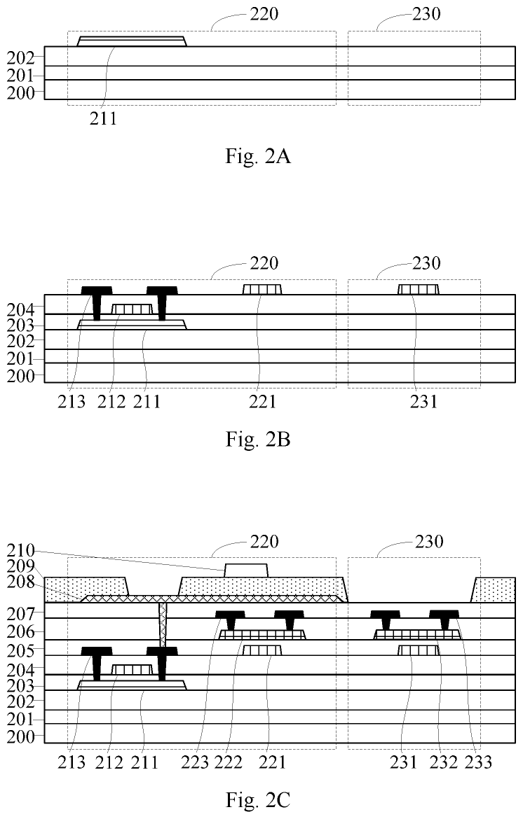

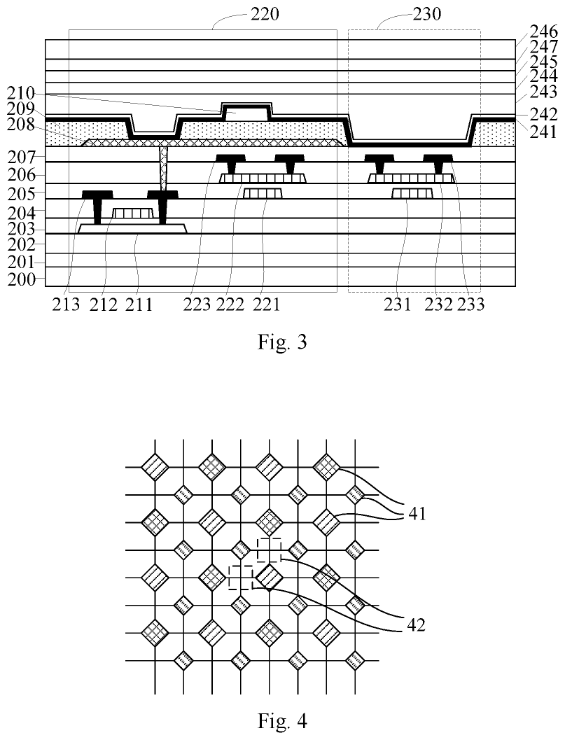

Please refer to FIG. 1, FIGS. 2A-2C and FIG. 3. FIG. 1 is a flow chart of a manufacturing method of a TFT array substrate according to an embodiment of the present invention. FIG. 2A-FIG. 2C depict structures at steps of a manufacturing method of a TFT array substrate according to an embodiment of the present invention. FIG. 3 is a diagram of a film layer structure of an OLED touch display device according to a first embodiment of the present invention.

The manufacturing method comprises following steps: S11: providing a substrate, comprising a plurality of pixel driving areas and at least one under screen fingerprint area. S12: forming a first low temperature poly-silicon (LTPS) TFT and a first oxide TFT on the pixel driving areas. In this embodiment, a gate of the first oxide TFT and a source/drain or a gate of the first LTPS TFT are formed through one patterning process. S13: forming a third TFT on the under screen fingerprint area. S14: forming a planarization layer on a location corresponding the pixel driving area and the under screen fingerprint area on the first oxide TFT. S15: forming an anode on a location corresponding to the pixel driving area on the planarization layer. In this embodiment, the anode is electrically connected to the first LTPS TFT through a via. S16: forming a pixel definition layer on a location corresponding to pixel driving area on the planarization layer. In this embodiment, the pixel definition layer exposes the anode. In this embodiment, the first LTPS TFT, the first oxide TFT and the third TFT are manufactured in a single array process.

In this embodiment, the third TFT is a second oxide TFT. The array process of the TFT array substrate comprises following steps:

(1) As shown in FIG. 2, a polyimide (PI) layer 201 is deposited on the glass substrate 200 and then a buffer layer 202 is formed. Then, the first poly-silicon active layer 211 of the first LTPS TFT is manufactured at a location corresponding to the pixel driving area 220. In this embodiment, the PI layer is deposited through a spreading process and then the buffer layer is formed through a CVD process. In addition, the poly-silicon film is formed on the buffer layer through a LTPS process and the poly-silicon film is formed at a location corresponding to the pixel driving area 220 of the poly-silicon layer through a single patterning process.

(2) As shown in FIG. 2B, the first inorganic insulating layer (GI1) 203 is manufactured. The first gate (Gate1) of the first LTPS TFT is manufactured on the GI1 layer 203. Then, the first inorganic dielectric layer (ILD1) 204 is manufactured. The first SD connection via is formed in the ILD1 layer 204. Through a single patterning process, the first source/drain 213 of the first LTPS TFT, the second gate 221 of the first oxide TFT are formed on the pixel driving area 220 and the third gate 231 of the second oxide TFT is formed on the under screen fingerprint area 230. In an embodiment, the GI1 layer is manufactured through the CVD process. The gate Gate 1 is formed through the PVD process. The dielectric layer (ILD1) is formed through the CVD process. The SD connection via is formed through the laser drill process. The source/drain metal layer is deposited on the pixel driving area and the gate metal layer is simultaneously deposited on the under screen fingerprint area 230 through the PVD process and source/drain metal layer and the gate metal layer are patterned to form the first source/drain 213, the second gate, and the third gate 231 located in the same layer.

(3) As shown in FIG. 2C, the second dielectric layer (ILD2) 205 is manufactured and the second oxide active layer 222 of the first oxide TFT and the third oxide active layer 232 of the second oxide TFT are manufactured through a single patterning process. The second inorganic insulating layer (GI2) 206 is manufactured and the second SD connection via is formed. The second source/drain 223 of the first oxide TFT and the third source/drain 233 of the second oxide TFT are manufactured through one single patterning process. Then, the planarization layer (PLN) 207 are formed at a location corresponding to the pixel driving area and the under screen fingerprint area 230. Then, the anode 208 is formed and then the pixel definition layer (PDL) 209 and the pressure support (PS) 210 are formed. There is no anode and pixel definition layer on the under screen fingerprint area 230 such that more light could enter the fingerprint identification sensor (the second oxide TFT). In an embodiment, the ILD2 layer is manufactured through the CVD process. The oxide active layer 222 and the oxide active layer 232 are manufactured through the PVD process. The GI2 layer is manufactured through the CVD process. The second SD connection via is formed through the laser drill process. The source/drain metal layer is deposited on the pixel driving area 220 and the under screen fingerprint area 230 through the PVD process. Then the source/drain metal layer is patterned to form the second source/drain 223 and the third source/drain 233 located in the same layer. The planarization layer 207 is manufactured with an organic material.

Here, the TFT array substrate is generally manufactured. The first LTPS TFT is used to drive the pixel to generate light. The first oxide TFT is used to perform a switch control. The second oxide TFT is used to perform the fingerprint identification.

In this embodiment, the manufacturing method could manufacture the LTPO and FOD techniques in a single array process step. This saves the manufacturing time and reduces the cost. In addition, the LTPO, having higher response speed and lower power consumption, is used to generate light. Further, the thin film optical fingerprint sensor is simultaneously manufactured on the LTPO substrate to realize under screen fingerprint identification. Here, the gate of the oxide TFTs (the first oxide TFT and the second oxide TFT) and the source/drain of the LTPS TFT are manufactured at the same time to save the cost of mask. In addition, the oxide TFT is adopted as the under screen fingerprint sensor to realize the light sensing function. That is, the light generated by the organic light emitting layer (EL) is reflected by the cover plate (window) of the display and then enters the oxide TFT. The oxide TFT senses the luminance change to generate a variance of a light current and thus realizes the fingerprint identification. In this way, the display could reduce power consumption and have higher screen ratio and under screen fingerprint function.

Furthermore, the manufacturing process for the TFT array substrate of the OLED touch display device could further comprise following step:

(4) As shown in FIG. 3, the organic light emitting layer (EL) 241 and the cathode layer 242 are manufactured. Then, the thin film packaging layer (TFE) 243 is manufactured. And then, the touch control layer (DOT) 244, the polarizer 245 and the cover plate (window) 246 are manufactured. The cover plate 246 could be adhesive to the POL through the optical glue (OCA) 247. In an embodiment, the EL layer and the cathode layer are manufactured through the deposition process. The TFE layer is manufactured through the CVD and IJP process. The manufacturing process of the DOT layer, the POL, and the cover plate are well known and thus omitted here.

Please refer to FIG. 3. The OLED touch display device manufactured by the above manufacturing method comprises: a TFT array substrate, an organic light emitting layer 241, positioned on the TFT array substrate; a cathode layer 242, positioned on the organic light emitting layer 241; a thin film packaging layer 243, positioned on the cathode layer 242; a touch control layer 244, positioned on the thin film packaging layer 243; a polarizer 245, positioned on the touch control layer 244; and a cover plate 246, positioned on the polarizer 245 and is adhesive to the polarizer 245 through the optical glue 247.

The TFT array substrate comprises a substrate 200, a first LTPS TFT, a first oxide TFT, a third TFT, a polarizer 207, an anode 208, a pixel definition layer 209, and a plurality of pressure supports 210.

The substrate 200 comprises a plurality of pixel driving areas 220 and at least one under screen fingerprint area 230. The first LTPS TFT is positioned on the pixel driving area 220 for driving the pixel to generate light. The first oxide TFT is positioned on the pixel driving area 220 for performing a switch control. Here, the second gate 221 of the first oxide TFT and the first source/drain of the first LTPS TFT are in the same layer. The third TFT is positioned on the under screen fingerprint area 230 for performing a fingerprint identification. The planarization layer 207 is positioned on the first oxide TFT and at a location corresponding to the pixel driving area 220 and the under screen fingerprint area 230. The anode 208 is positioned on the planarization layer 207 at a location corresponding to the pixel driving area 220. Here, the anode 208 is electrically connected to the first LTPS TFT through a via. The pixel definition layer 209 is positioned on the planarization layer 207 at a location corresponding to the pixel driving area 220. Here, the pixel definition 209 exposes a part of the anode 208. The pressure support 210 is positioned on the pixel definition layer 209 for supporting the following deposition of the OLED.

Furthermore, the third TFT is a second oxide TFT. The film layer structure of the second oxide TFT is the same as that of the first oxide TFT. Specifically, the third gate 231 of the second oxide TFT, the second gate 221 of the first oxide TFT, and the first source/drain 213 of the first LTPS TFT are in the same layer. The third oxide active layer 232 of the second oxide TFT, the second oxide active layer 222 of the first oxide TFT are in the same layer. The third source/drain 233 of the second oxide TFT and the second source/drain 223 of the first oxide TFT are in the same layer.

In this embodiment, the LTPO, having lower power consumption, is utilized to drive OLEDs to generate light and the thin film optical fingerprint sensor is formed on the LTPO substrate to realize the under screen fingerprint identification. In particular, the gate of the oxide TFT and the source/drain of the LTPS TFT are in the same layer to save the cost of the mask. In addition, the oxide TFT is adopted as the under screen fingerprint sensor to realize the light sensing function and thus realize the fingerprint identification. In addition, there is no anode and pixel definition layer on the under screen fingerprint area such that more light that could enter the oxide TFT. In this way, the display could reduce power consumption and have higher screen ratio and under screen fingerprint function.

Please refer to FIG. 4. FIG. 4 is a diagram of a distribution of the fingerprint sensor according to an embodiment of the present invention. In this embodiment, the TFT array substrate comprises a plurality of pixel driving areas and at least one under screen fingerprint area. The under screen fingerprint area is positioned between adjacent two pixel driving areas. Each of the pixel driving areas has a sub-pixel (R/G/B) 41. Each of the under screen fingerprint area has a fingerprint sensor 42. The fingerprint sensor 42 could be implemented by an oxide TFT or a LTPS TFT.

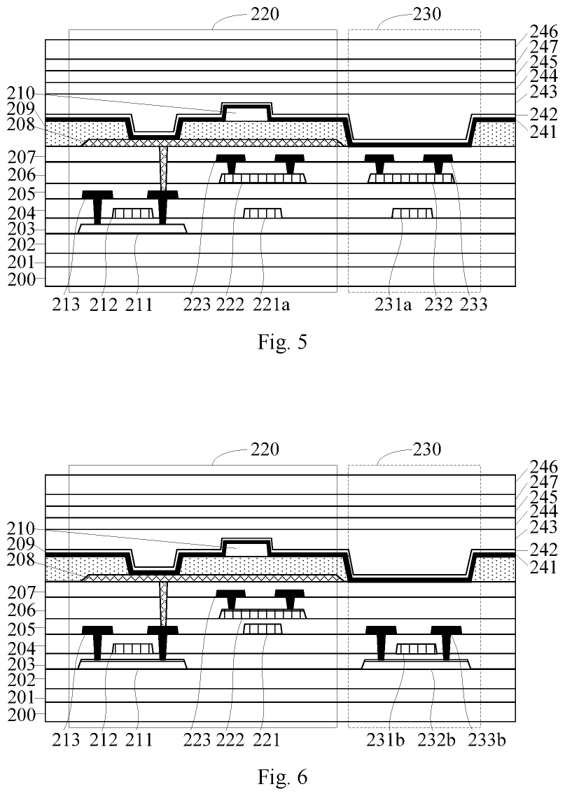

Please refer to FIG. 1 and FIG. 5. FIG. 5 is a diagram of a film layer structure of an OLED touch display device according to a second embodiment of the present invention. The difference between the second embodiment of FIG. 5 and the first embodiment of FIG. 3 is: in this embodiment, the third gate 231a of the second oxide TFT, the second gate 221a of the first oxide TFT and the first gate 212 of the first LTPS are in the same layer. That is, in the corresponding manufacturing method, the third gate 231a of the second oxide TFT, the second gate 221a of the first oxide TFT and the first gate 212 of the first LTPS are manufactured through one single patterning process.

In this embodiment, the LTPO, having lower power consumption, is utilized to drive OLEDs to generate light and the thin film optical fingerprint sensor is formed on the LTPO substrate to realize the under screen fingerprint identification. In particular, the gate of the oxide TFT and the gate of the LTPS TFT are in the same layer to save the cost of the mask. In addition, the oxide TFT is adopted as the under screen fingerprint sensor to realize the light sensing function and thus realize the fingerprint identification. In addition, there is no anode and pixel definition layer on the under screen fingerprint area such that more light that could enter the oxide TFT. In this way, the display could reduce power consumption and have higher screen ratio and under screen fingerprint function.

Please refer to FIG. 1 and FIG. 6. FIG. 6 is a diagram of a film layer structure of an OLED touch display device according to a third embodiment of the present invention. The difference between the third embodiment of FIG. 6 and the first embodiment of FIG. 3 is: in this embodiment, the third TFT is a second LTPS TFT and the second LTPS TFT is positioned on the under screen fingerprint area 230 for performing the fingerprint identification.

In a further embodiment, the film layer structure of the second LTPS TFT is the same as the film layer structure of the first LTPS TFT. Specifically, the third poly-silicon active layer 232b of the second LTPS TFT and the poly-silicon active layer 211 of the first LTPS TFT are in the same layer. The third gate 231b of the second LTPS TFT and the first gate 212 of the first LTPS TFT are in the same layer. The third source/drain 233b of the second LTPS TFT, the first source/drain 213 of the first LTPS TFT and the second gate 221 of the first oxide TFT are in the same layer. That is, in the corresponding manufacturing method, the third source/drain 233b of the second LTPS TFT, the first source/drain 213 of the first LTPS TFT and the second gate 221 of the first oxide TFT are manufactured through one single patterning process.

In this embodiment, the LTPO, having lower power consumption, is utilized to drive OLEDs to generate light and the thin film optical fingerprint sensor is formed on the LTPO substrate to realize the under screen fingerprint identification. In particular, the gate of the oxide TFT and the source/drain of the LTPS TFT are in the same layer to save the cost of the mask. In addition, the LTPS TFT is adopted as the under screen fingerprint sensor to realize the light sensing function and thus realize the fingerprint identification. In addition, there is no anode and pixel definition layer on the under screen fingerprint area such that more light that could enter the LTPS TFT. In this way, the display could reduce power consumption and have higher screen ratio and under screen fingerprint function.

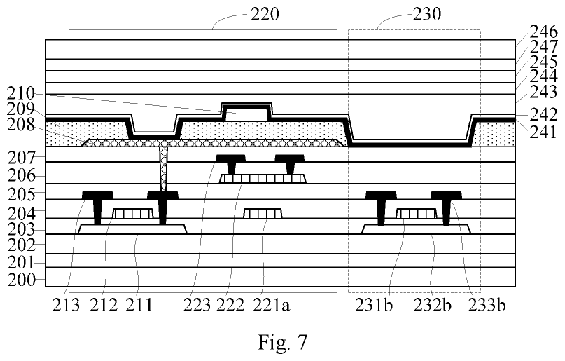

Please refer to FIG. 1 and FIG. 7. FIG. 7 is a diagram of a film layer structure of an OLED touch display device according to a fourth embodiment of the present invention. The difference between the fourth embodiment of FIG. 7 and the first embodiment of FIG. 3 is: in this embodiment, the third gate 231b of the second LTPS TFT, the first gate 212 of the first LTPS TFT and the second gate 221a of the first oxide TFT are in the same layer. That is, the third gate 231b of the second LTPS TFT, the first gate 212 of the first LTPS TFT and the second gate 221a of the first oxide TFT are manufactured through one single patterning process.

In this embodiment, the LTPO, having lower power consumption, is utilized to drive OLEDs to generate light and the thin film optical fingerprint sensor is formed on the LTPO substrate to realize the under screen fingerprint identification. In particular, the gate of the oxide TFT and the gate of the LTPS TFT are in the same layer to save the cost of the mask. In addition, the LTPS TFT is adopted as the under screen fingerprint sensor to realize the light sensing function and thus realize the fingerprint identification. In addition, there is no anode and pixel definition layer on the under screen fingerprint area such that more light that could enter the LTPS TFT. In this way, the display could reduce power consumption and have higher screen ratio and under screen fingerprint function.

Above are embodiments of the present invention, which does not limit the scope of the present invention. Any modifications, equivalent replacements or improvements within the spirit and principles of the embodiment described above should be covered by the protected scope of the invention.

1. A manufacturing method for manufacturing a thin film transistor (TFT) array substrate, the manufacturing method comprising:
providing a substrate comprising a plurality of pixel driving areas and at least one under screen fingerprint area;
forming a first low temperature poly-silicon (LTPS) TFT and a first oxide TFT on the pixel driving areas wherein a gate of the first oxide TFT and a source/drain or a gate of the first LTPS TFT are formed through one patterning process; and
forming a third TFT on the under screen fingerprint area;
wherein the first LTPS TFT is configured to drive a pixel to generate light, the first oxide TFT is configured to perform a switch control, and the third TFT is configured to perform a fingerprint identification.

2. The manufacturing method of claim 1, wherein the third TFT is a second oxide TFT;
wherein a gate of the second oxide TFT, the gate of the first oxide TFT, and source/drain or the gate of the first LTPS TFT are formed through one patterning process;
wherein an oxide active layer of the second oxide TFT and an oxide active layer of the first oxide TFT are formed through one patterning process; and
wherein a source/drain of the second oxide TFT and the source/drain of the first oxide TFT are formed through one patterning process.

3. The manufacturing method of claim 1, wherein the third TFT is a second LTPS TFT;
wherein a poly-silicon active layer of the second LTPS TFT and a poly-silicon active layer of the first LTPS TFT are formed through one patterning process;
wherein a gate of the second LTPS TFT and a gate of the first LTPS TFT are formed through one patterning process; and
wherein a source/drain of the second LTPS TFT and the source/drain of the first LTPS TFT are formed through one patterning process.

4. The manufacturing method of claim 1, further comprising:
forming a planarization layer on a location corresponding the pixel driving area and the under screen fingerprint area on the first oxide TFT;
forming an anode on a location corresponding to the pixel driving area on the planarization layer wherein the anode is electrically connected to the first LTPS TFT through a via; and
forming a pixel definition layer on a location corresponding to pixel driving area on the planarization layer, wherein the pixel definition layer exposes the anode.

5. A TFT array substrate, comprising:
a substrate, comprising a plurality of pixel driving areas and at least one under screen fingerprint area;
a first LTPS TFT, positioned on a the pixel driving area, configured to drive a pixel to generate light;
a first oxide TFT, positioned on the pixel driving area, configured to perform a switch control, wherein a gate of the first oxide TFT and a gate of the first LTPS TFT are in a different layers; and
a third TFT, positioned on the under screen fingerprint area, configured to perform a fingerprint identification.

6. The TFT array substrate of claim 5, wherein the under screen fingerprint area is located between two adjacent pixel driving areas.

7. The TFT array substrate of claim 5, wherein the third TFT is a second oxide TFT;
wherein a gate of the second oxide TFT, the gate of the first oxide TFT, and source/drain or the gate of the first LTPS TFT are in a same layer;
wherein an oxide active layer of the second oxide TFT and an oxide active layer of the first oxide TFT are in a same layer; and
wherein a source/drain of the second oxide TFT and the source/drain of the first oxide TFT are in a same layer.

8. The TFT array substrate of claim 5, wherein the third TFT is a second LTPS TFT;
wherein a poly-silicon active layer of the second LTPS TFT and a poly-silicon active layer of the first LTPS TFT are in a same layer;
wherein a gate of the second LTPS TFT and a gate of the first LTPS TFT are in a same layer; and
wherein a source/drain of the second LTPS TFT and the source/drain of the first LTPS TFT are in a same layer.

9. The TFT array substrate of claim 5, further comprising:
a planarization layer, positioned on a location corresponding the pixel driving area and the under screen fingerprint area on the first oxide TFT;
an anode, positioned on a location corresponding to the pixel driving area on the planarization layer wherein the anode is electrically connected to the first LTPS TFT through a via; and
a pixel definition layer, positioned on a location corresponding to pixel driving area on the planarization layer, wherein pixel definition layer exposes the anode.

10. An organic light emitting diode (OLED) display, comprising:
a TFT array substrate, comprising:
a substrate, comprising a plurality of pixel driving areas and at least one under screen fingerprint area;
a first LTPS TFT, positioned on the a pixel driving area, configured to drive a pixel to generate light;
a first oxide TFT, positioned on the pixel driving area, configured to perform a switch control, wherein a gate of the first oxide TFT and a gate of the first LTPS TFT are in different layers; and
a third TFT, positioned on the under screen fingerprint area, configured to perform a fingerprint identification;
an organic light emitting layer, positioned on the TFT array substrate;
a cathode layer, positioned on the organic light emitting layer;
a thin film packaging layer, positioned on the cathode layer;
a touch control layer, positioned on the thin film packaging layer;
a polarizer, positioned on the touch control layer; and
a cover plate, positioned on the polarizer.

11. The OLED display of claim 10, wherein the under screen fingerprint area is located between two adjacent pixel driving areas.

12. The OLED display of claim 10, wherein the third TFT is a second oxide TFT;
wherein a gate of the second oxide TFT, the gate of the first oxide TFT, and source/drain or the gate of the first LTPS TFT are in a same layer;
wherein an oxide active layer of the second oxide TFT and an oxide active layer of the first oxide TFT are in a same layer; and
wherein a source/drain of the second oxide TFT and the source/drain of the first oxide TFT are in a same layer.

13. The OLED display of claim 10, wherein the third TFT is a second LTPS TFT;
wherein a poly-silicon active layer of the second LTPS TFT and a poly-silicon active layer of the first LTPS TFT are in a same layer;
wherein a gate of the second LTPS TFT and a gate of the first LTPS TFT are in a same layer; and
wherein a source/drain of the second LTPS TFT and the source/drain of the first LTPS TFT are in a same layer.

14. The OLED display of claim 10, wherein the TFT array substrate further comprises:
a planarization layer, positioned on a location corresponding the pixel driving area and the under screen fingerprint area on the first oxide TFT;
an anode, positioned on a location corresponding to the pixel driving area on the planarization layer wherein the anode is electrically connected to the first LTPS TFT through a via; and
a pixel definition layer, positioned on a location corresponding to pixel driving area on the planarization layer, wherein pixel definition layer exposes the anode.
